(19) United States
(12) Patent Application Publication
(10) Pub. No.: US 2026/0287158 A1
(43) Pub. Date: Sep. 24, 2026

(54) HEADLIGHT

(71) Applicant: TJM DESIGN CORPORATION, Itabashi-ku, Tokyo (JP)

(72) Inventor: Tsuyoshi WATANABE, Itabashi-ku, Tokyo (JP)

(73) Assignee: TJM DESIGN CORPORATION, Itabashi-ku, Tokyo (JP)

(21) Appl. No.: 18/996,234

(22) PCT Filed: Jul. 31, 2024
(86) PCT No.: PCT/JP2024/027396

§ 371 Date: Jan. 17, 2025

(30) Foreign Application Priority Data
Aug. 10, 2023 (JP) 2023-131602

(51) Int. Cl. F21V 23/00; F21S 41/141; F21S 45/47; F21V 15/00

(52) U.S. Cl. CPC F21V 23/008; F21S 41/141; F21S 45/47; F21V 15/005

(57) ABSTRACT

To provide a headlight that is excellent in terms of protection from heat generated by a light-emitting device. A headlight (10A) includes a light-emitting device (3), a control board (5), a light-emitting-device-housing space (S1) that houses the light-emitting device (3), and a control-board-housing space (S2) that houses the control board (5). The light-emitting-device-housing space (S1) and the control-board-housing space (S2) are different spaces.

### TECHNICAL FIELD

The present invention relates to a headlight. The present application claims priority to Japanese Patent Application No. 2023-131602 filed in Japan on Aug. 10, 2023, the entire contents of which are incorporated herein by reference.

### BACKGROUND ART

Headlights are used in, for example, nighttime work, construction sites at underground levels or the like, and so forth. Therefore, headlights are desired to be usable with a constantly high power output for long hours.

In terms of emitting light with a high power output for long hours, however, the light-emitting device is considered to generate a large amount of heat, with a long time period of heat generation.

Accordingly, for the purpose of protecting a control circuit board including a board and a chip, a known headlight includes a heat-radiating column attached to a housing that houses an LED (light-emitting-diode) holder on which an LED package including an LED element is mounted, or includes a fan device provided in addition to the heat-radiating column (see PTL 1, for example).

In another known headlight, an LED light source is soldered to a protrusion formed on a heat-conducting plate and protruding through an opening provided in a PCB (printed circuit board), and a heat sink is placed on the heat-conducting plate, whereby the LED light source is cooled (see PTL 2, for example).

### CITATION LIST

### Patent Literature

PTL 1: Japanese Patent No. 6460469

PTL 2: Japanese Patent No. 5627795

### SUMMARY OF INVENTION

### Technical Problem

In each of the above known headlights, however, the light-emitting device (LED) is included in a control board. Such a configuration still has room for improvement in terms of protecting the control board from heat.

An object of the present invention is to provide a headlight that is excellent in terms of protection from heat generated by a light-emitting device.

### Solution to Problem

(1) A headlight according to the present invention includes a light-emitting device, a control board, a light-emitting-device-housing space that houses the light-emitting device, and a control-board-housing space that houses the control board. The light-emitting-device-housing space and the control-board-housing space are different spaces.

(2) The headlight according to (1) described above may further include a head body and a head frame. The light-emitting-device-housing space may be provided in the head body, and the control-board-housing space may be provided in the head frame.

(3) In the headlight according to (2) described above, the head frame may include a base frame and two side frames, and the control-board-housing space may be provided in one of the two side frames.

(4) In the headlight according to (3) described above, one of the two side frames may be provided with a switch, and the one side frame may have the control-board-housing space.

(5) In the headlight according to (3) or (4) described above, one of the two side frames may be provided with a power cable connected to a power box, and the one side frame or the power box may have the control-board-housing space.

(6) In the headlight according to any of (2) to (5) described above, the head body may be rotatably supported by the head frame.

(7) The headlight according to any of (1) to (6) described above may further include heat-radiating means, and the heat-radiating means may be housed in the light-emitting-housing space and be located adjacent to the light-emitting device.

(8) In the headlight according to (7) described above, the heat-radiating means may be a heat sink.

(9) In the headlight according to (7) or (8) described above, the heat-radiating means may include a front cylindrical part that houses the light-emitting device, and a recessed portion may be provided on an inner side of the front cylindrical part.

### Advantageous Effects of Invention

According to the present invention, a headlight that is excellent in terms of protection from heat generated by a light-emitting device is provided.

### BRIEF DESCRIPTION OF DRAWINGS

FIG. 1 is a front view of a headlight according to a first embodiment of the present invention.

FIG. 2 is a plan view of the headlight illustrated in FIG. 1.

FIG. 3 is a bottom view of the headlight illustrated in FIG. 1.

FIG. 4 is a rear view of the headlight illustrated in FIG. 1.

FIG. 5 is a left side view of the headlight illustrated in FIG. 1.

FIG. 6 is a right side view of the headlight illustrated in FIG. 1.

FIG. 7 is a perspective view of the headlight illustrated in FIG. 1.

FIG. 8 is a perspective view of the headlight illustrated in FIG. 7, with a switch, a switch knob, and a side cover removed.

FIG. 9 is a perspective view of the headlight illustrated in FIG. 8, with a part of a head body removed.

FIG. 10 is a perspective view of the headlight illustrated in FIG. 9, with another part of the head body further removed.

FIG. 11 is a perspective view of the headlight illustrated in FIG. 10, with yet another part of the head body further removed.

FIG. 12 is a schematic perspective view of first heat-radiating means and second heat-radiating means, illustrated in FIG. 11, that are assembled together.

FIG. 13 schematically illustrates, in perspective view, a state where a heat-sink gasket is fitted in a through-hole provided in the first heat-radiating means illustrated in FIG. 12.

FIG. 14 is a sectional view of the headlight illustrated in FIG. 3 and schematically illustrates a section containing the rotation axis of the headlight.

FIG. 15 is a perspective view of the headlight illustrated in FIG. 1, with the head body and a part of a head frame removed.

FIG. 16 is a perspective view of the headlight illustrated in FIG. 1, with the head body, the part of the head frame, and a part of a heat sink removed.

FIG. 17 illustrates chronological analysis data on the brightness of light emitted from the headlight illustrated in FIG. 1 when the headlight continues to be used with a constant power output of 100%.

FIG. 18 is a schematic perspective view of a headlight according to a second embodiment of the present invention.

FIG. 19 is a schematic perspective view of a headlight according to a third embodiment of the present invention.

FIG. 20 is a diagram schematically illustrating a power box for a headlight according to a fourth embodiment of the present invention.

FIG. 21 is a schematic front view of a headlight according to a fifth embodiment of the present invention.

FIG. 22 is a diagram schematically illustrating a shell-type LED device serving as a light-emitting device of a headlight.

FIG. 23 is a diagram schematically illustrating a chip-on-board LED device that is available as a light-emitting device of a headlight.

### DESCRIPTION OF EMBODIMENTS

Headlights according to exemplary embodiments of the present invention will now be described with reference to the drawings. Herein, the front, rear, left, and right are defined with reference to a user wearing the headlight.

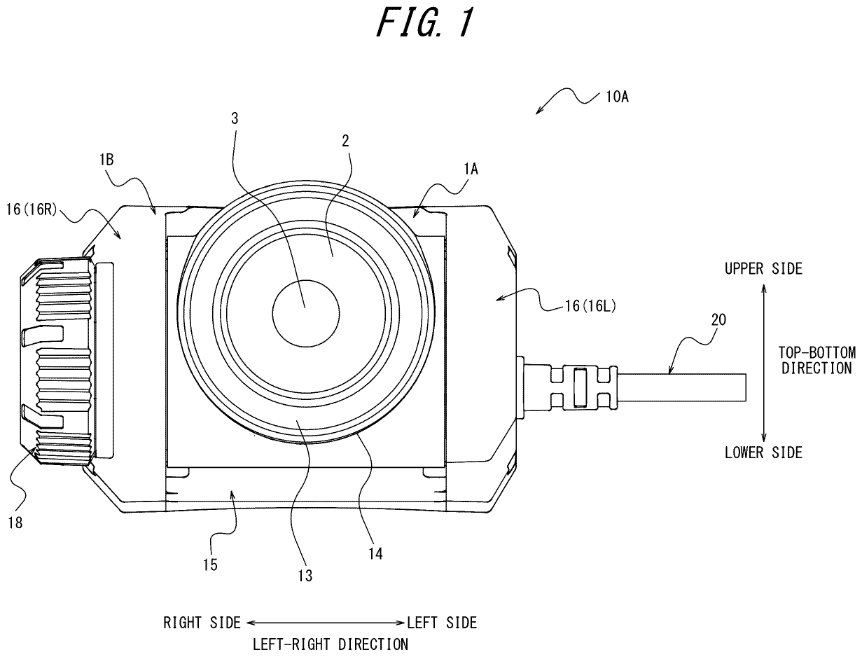

FIG. 1 illustrates a headlight 10A according to a first embodiment of the present invention that is seen from the front side. The headlight 10A includes a light source such as a light-emitting device and is attachable to a helmet (not illustrated) to be worn by the user, with the aid of, for example, a belt (band). The headlight 10A is to be used in, for example, nighttime work, construction sites at underground levels or the like, and so forth.

The headlight 10A according to the present embodiment includes a head body 1A, which includes a lens 2 and a light-emitting device 3; and a head frame 1B, which is attached to the head body 1A. The headlight 10A is attachable to a helmet with the aid of a belt (not illustrated) that is passed through the head frame 1B.

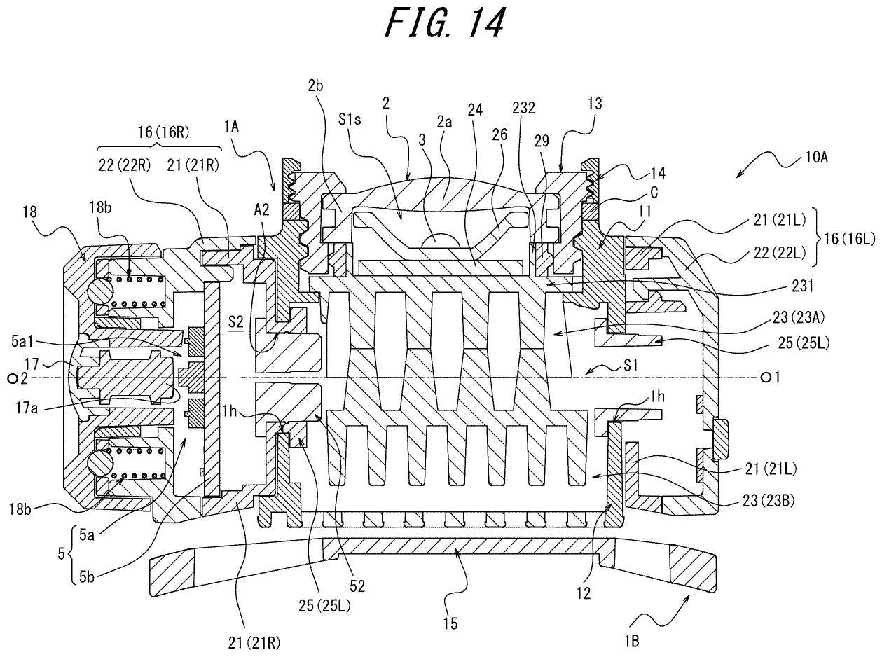

In the present embodiment, as to be described separately below with reference to FIG. 14, the head body 1A has thereinside a light-emitting-device-housing space S1, which houses the light-emitting device 3. In the present embodiment, the light-emitting-device-housing space S1 houses the lens 2, the light-emitting device 3, and heat-radiating means 23. The lens 2 adjusts the focus of light emitted from the light-emitting device 3 and traveling through the lens 2. In the present embodiment, the light-emitting device 3 is a shell-type LED device.

In the headlight 10A according to the present embodiment, setting the light emitted from the light-emitting device 3 and through the lens 2 to be focused on a position close to the headlight 1 enables predominant spot illumination of a near target position. Furthermore, in the headlight 10A according to the present embodiment, setting the light emitted from the light-emitting device 3 and through the lens 2 to be focused on a position far from the headlight 10A enables predominant long-distance illumination of a distant target position over a wider area.

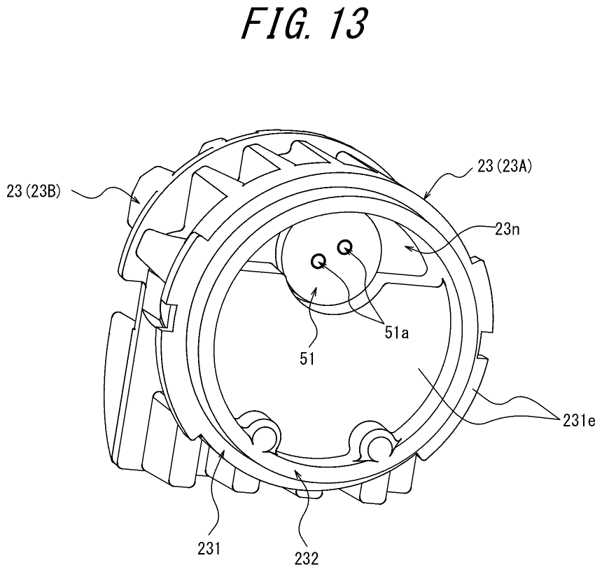

In the present embodiment, the light-emitting device 3 is located rearward of the lens 2. In the present embodiment, the lens 2 includes a lens body 2a, which determines the focus of the light; and a circular cylindrical part 2b (see FIG. 13), which extends in the front-rear direction from the outer edge of the lens body 2a. In the present embodiment, the lens 2 is closed by a front ring 13. In the present embodiment, the front ring 13 is an annular member. In the present embodiment, the front ring 13 is threaded to be attached to the inner side of a front body 11, which will be described separately below. In the present embodiment, a front-ring cover 14 is threaded to be attached to the outer side of the front ring 13. In the present embodiment, a cylindrical collar C is interposed between the front-ring cover 14 and the front body 11.

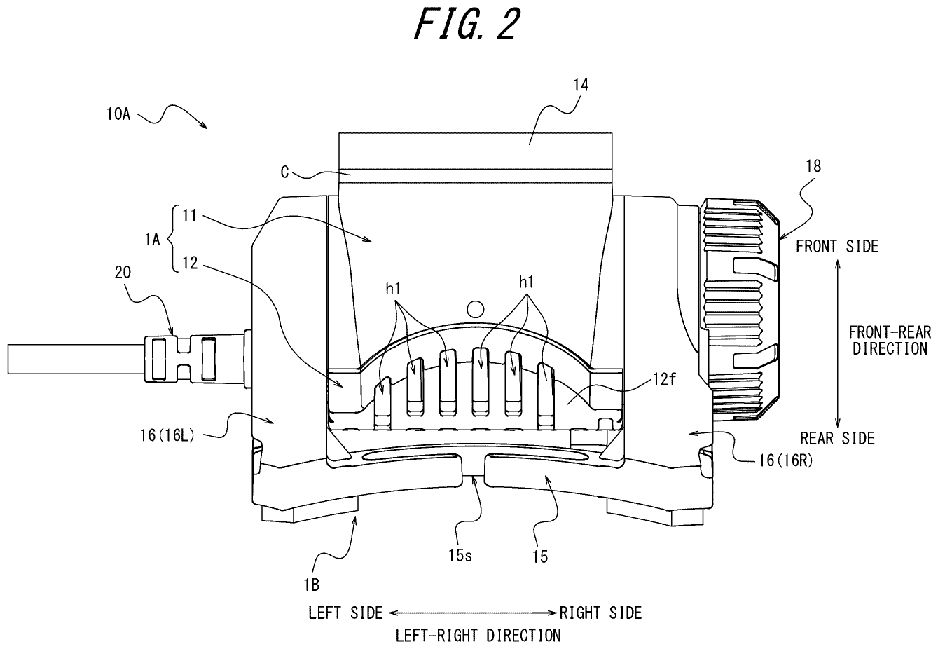

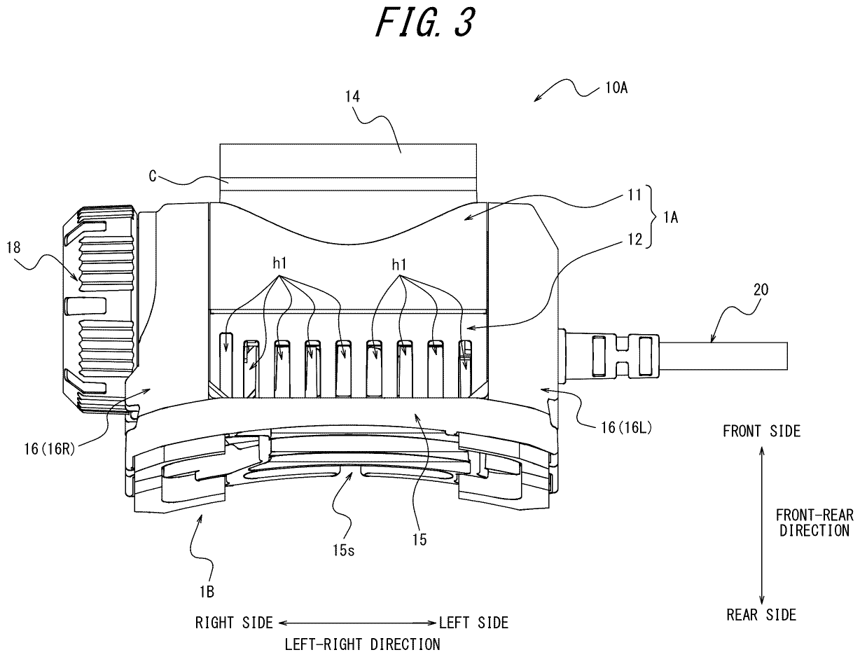

FIG. 2 illustrates the headlight 10A seen from above in a planar manner. FIG. 3 illustrates the headlight 10A seen from below in a planar manner.

In the present embodiment, the head body 1A includes the front body 11 and a rear body 12. In the present embodiment, the rear end of the front body 11 receives the front end of the rear body 12. In the present embodiment, the front-ring cover 14 and the collar C are attached to the front body 11. In the present embodiment, the rear body 12 has a plurality of vent holes h1. In the present embodiment, as illustrated in FIG. 2, the rear body 12 has at the upper surface thereof a slope 12f.

On the other hand, the head frame 1B includes a base frame 15 and two side frames 16. In the present embodiment, the base frame 15 extends in the left-right direction (widthwise direction). In the present embodiment, the two side frames 16 extend frontward from the respective widthwise ends of the base frame 15. In the present embodiment, the head body 1A is located between the two side frames 16.

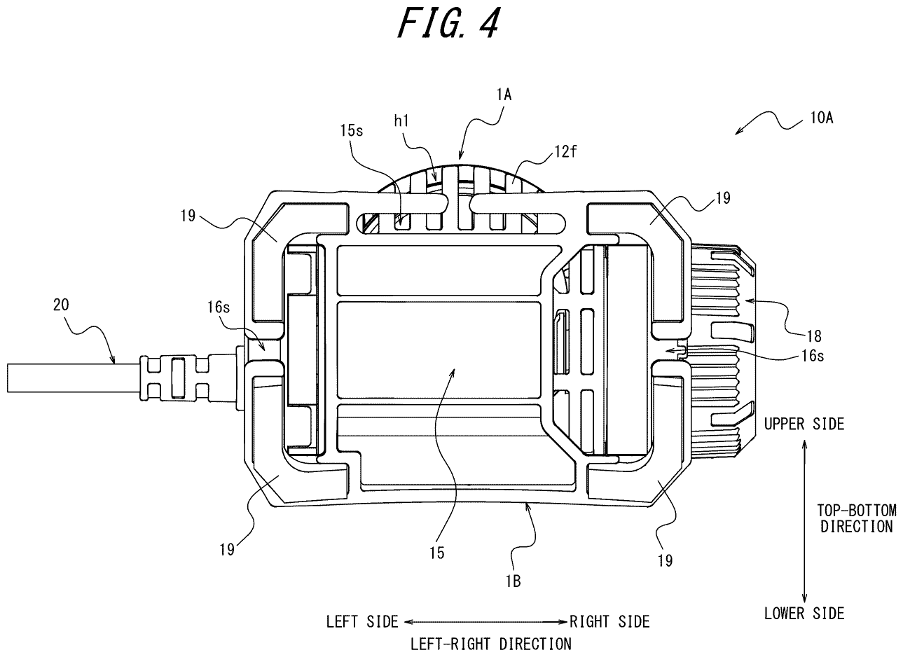

FIG. 4 illustrates the headlight 10A seen from the rear side.

In the present embodiment, as illustrated in FIG. 4, the base frame 15 is provided at the rear face thereof with cushion members 19. The cushion members 19 are each a shock-absorbing member to be interposed between the base frame 15 and the helmet. In the present embodiment, the base frame 15 is provided with four cushion members 19. In the present embodiment, as illustrated in FIG. 4, the four cushion members 19 are located at the four respective corners, in the top-bottom and left-right directions, of the base frame 15. In the present embodiment, the cushion members 19 are made of urethane foam resin. Note that the material of the cushion members 19 is not limited to urethane foam resin. The base frame 15 has in an upper part thereof a slit opening 15s, which is provided for a second belt (not illustrated) to pass through.

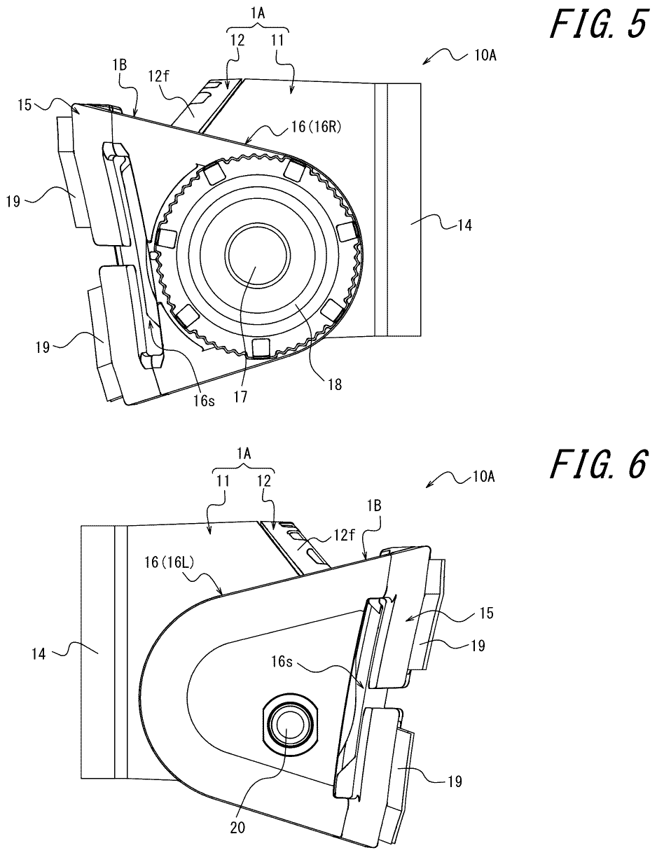

FIG. 5 is a left side view of the headlight 10A illustrated in FIG. 1. In the following description, “right” is defined with reference to the user wearing the headlight 10A.

As illustrated in FIG. 5, in the present embodiment, one of the two side frames 16 (hereinafter also referred to as “right side frame 16R”) is provided with a switch 17, which is capable of turning on/off a circuit element (5a1) included in a control board 5. In the present embodiment, the switch 17 is a switch for adjusting the intensity of the light emitted from the headlight 10A through the lens 2. In the present embodiment, the switch 17 is attached to a switch knob 18, which is attached to the right side frame 16R. The right side frame 16R has a slit opening 16s, which is provided for a first belt (not illustrated) to pass through. In the present embodiment, the first belt is a belt that is made to pass through the slit opening 16s and is thus fixed to the headlight 10A so as to be wrapped around the head. The second belt is attached at one end thereof to the first belt and is also attached at the other end thereof to the headlight 10A by being made to pass through the slit opening 15s of the base frame 15.

FIG. 6 is a right side view of the headlight 10A illustrated in FIG. 1. In the following description, “left” is defined with reference to the user wearing the headlight 10A.

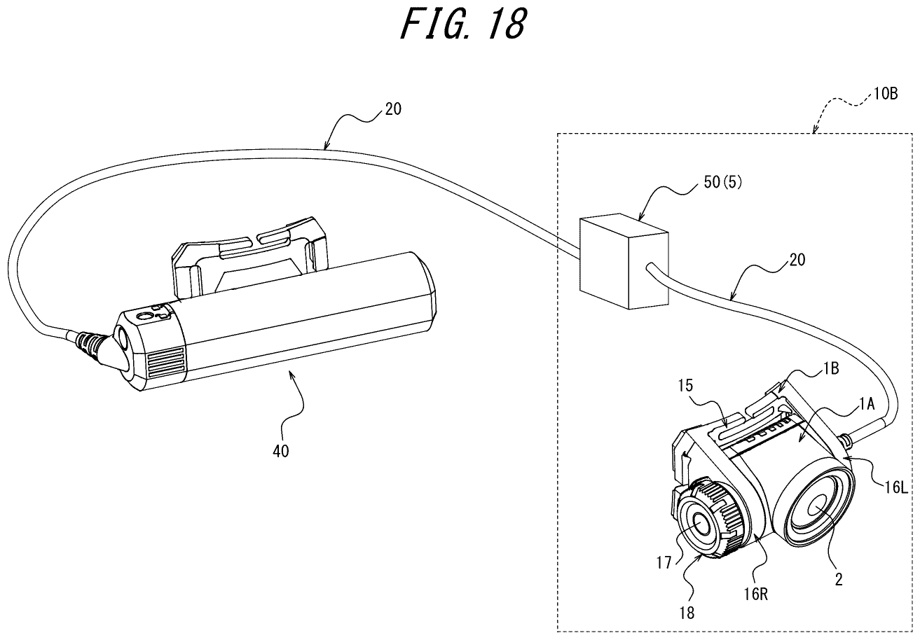

As illustrated in FIG. 6, in the present embodiment, the other of the two side frames 16 (hereinafter also referred to as “left side frame 16L”) is provided with a power cable 20, which is connected to a power box 40 (see FIG. 18, for example). As illustrated in FIG. 6, the left side frame 16L also has a slit opening 16s, which is provided for the first belt to pass through.

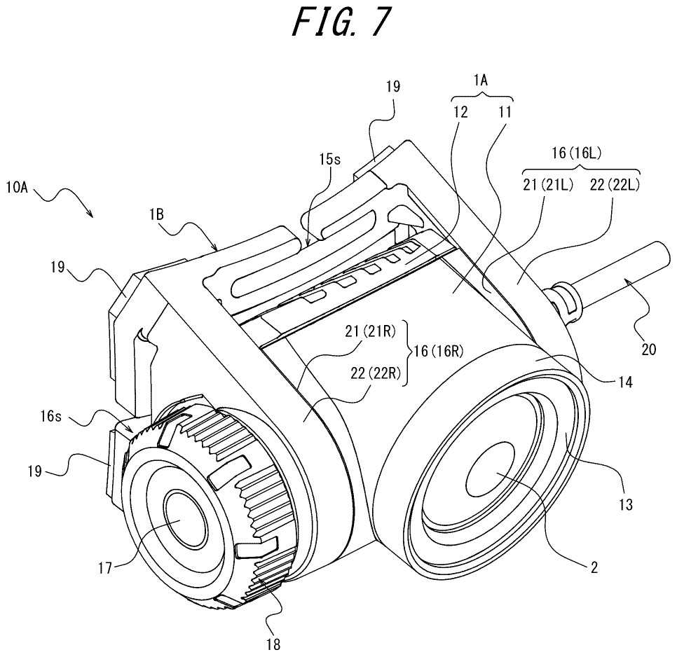

FIG. 7 illustrates the headlight 10A seen from the upper right in a perspective manner. As illustrated in FIG. 7, in the present embodiment, the side frames 16 each include a side base 21, which is continuous with the base frame 15; and a side cover 22, which is attached to the side base 21. In the present embodiment, between the side base 21 and the side cover 22 is provided an internal space enclosed by the side base 21 and the side cover 22.

In the present embodiment, reference sign 16R denotes the right side frame provided on the right side. The right side frame 16R is constituted by a right side base 21R and a right side cover 22R. In the present embodiment, reference sign 16L denotes the left side frame provided on the left side. In the present embodiment, the left side frame 16L is constituted by a left side base 21L and a left side cover 22L.

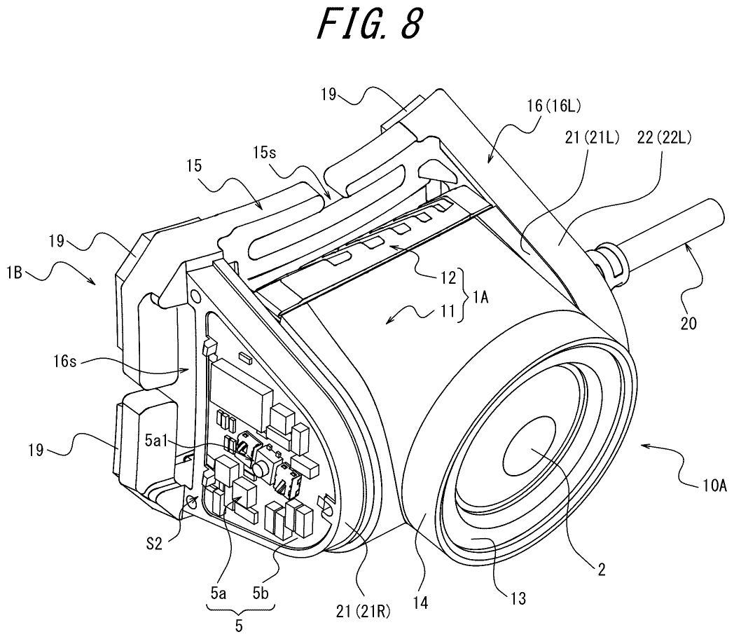

FIG. 8 schematically illustrates the headlight 10A illustrated in FIG. 7, with the switch 17, the switch knob 18, and the right side cover 22R removed.

In the present embodiment, the control board 5 is a control circuit board in which a plurality of circuit elements (chips) 5a are mounted on a board 5b. The circuit elements 5a are intended to control the light-emitting device 3. Reference sign 5a1 denotes one of the plurality of circuit elements 5a that serves as a power switch element.

The control board 5 is housed in a control-board-housing space S2, which may be provided in one of the two side frames 16.

In the present embodiment, the control-board-housing space S2 is provided in the right side frame 16R. The control-board-housing space S2 is an internal space provided between the right side base 21R and the right side cover 22R.

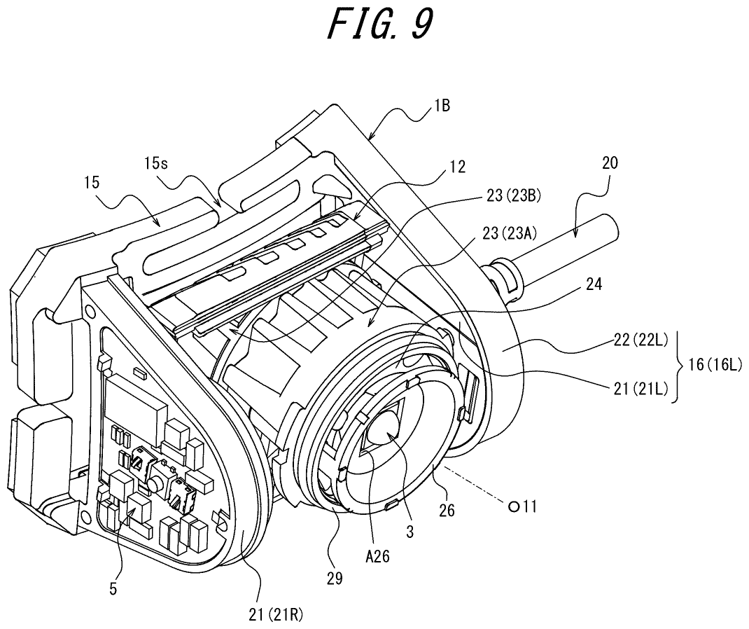

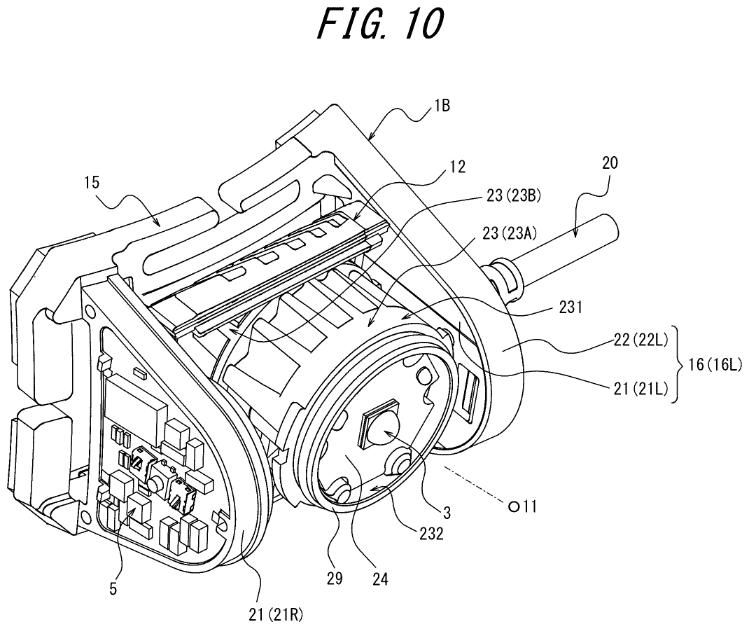

FIG. 9 is a perspective view of the headlight 10A illustrated in FIG. 8, with a part of the head body 1A further removed. In FIG. 9, the removed part includes the front body 11 of the head body 1A, the lens 2, the front ring 13, the front-ring cover 14, and the collar C.

In the present embodiment, between the light-emitting device 3 and the lens 2 is provided a lens spacer 26. The lens spacer 26 has an opening A26, through which the light-emitting device 3 passes. The lens spacer 26 is a conical member whose diameter increases frontward. The lens spacer 26 adjusts the distance between the lens 2 (lens body 2a) and the light-emitting device 3. In the present embodiment, the lens spacer 26 is attached to a mounting board 24. In the present embodiment, the lens spacer 26 holds the lens 2 from the rear side.

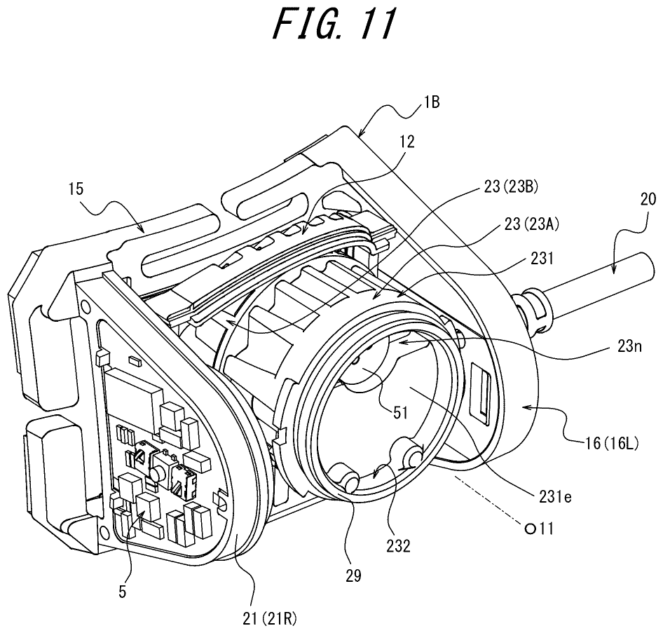

FIG. 10 is a perspective view of the headlight 10A illustrated in FIG. 9, with another part of the head body 1A further removed. In FIG. 10, the further removed part is the lens spacer 26. As illustrated in FIG. 10, in the present embodiment, the light-emitting device 3 is mounted on the mounting board 24.

In the present embodiment, the mounting board 24 is located between the light-emitting device 3 and the heat-radiating means 23. In the present embodiment, the mounting board 24 is a board intended to attach the light-emitting device 3 to the heat-radiating means 23. In the present embodiment, the light-emitting device 3 is mounted on the mounting board 24. The mounting board 24 is attached to the heat-radiating means 23.

The heat-radiating means 23 is means for releasing heat generated from the light-emitting device 3. In the present embodiment, the heat-radiating means 23 is housed in the light-emitting-device-housing space S1 provided inside the head body 1A. In the present embodiment, the heat-radiating means 23 is located adjacent to the light-emitting device 3.

In the present embodiment, the heat-radiating means 23 is a heat sink. The heat sink includes a plurality of heat-radiating plates and is made of a highly heat-conductive material: for example, a metal such as an aluminum alloy.

The headlight 10A according to the present embodiment includes two heat-radiating means: first heat-radiating means 23A and second heat-radiating means 23B. As illustrated in FIG. 10, in the present embodiment, the two heat-radiating means 23 of the first heat-radiating means 23A and the second heat-radiating means 23B are arranged in series together with the light-emitting device 3 on the optical axis, O11, of the headlight 10A (lens body 2a). In the present embodiment, the first heat-radiating means 23A includes a body 231, which includes a plurality of heat-radiating plates; and a front cylindrical part 232, which projects frontward from the body 231. In the present embodiment, the front cylindrical part 232 is provided at the outer peripheral surface thereof with a heat-sink gasket (heat-radiating-means sealing member) 29. The heat-sink gasket (hermetic stopper) 29 is an annular sealing member. As illustrated in FIG. 10, in the present embodiment, the mounting board 24 is located on the inner side of the front cylindrical part 232 of the first heat-radiating means 23A.

FIG. 11 is a perspective view of the headlight 10A illustrated in FIG. 10, with yet another part of the head body 1A further removed. In FIG. 11, the further removed part is the mounting board 24. As illustrated in FIG. 11, the first heat-radiating means 23A has a recessed portion 23n, which is located on the inner side of the front cylindrical part 232. In the present embodiment, the recessed portion 23n is provided by causing a portion of the front end, 231e, of the body 231 that is on the inner side of the front cylindrical part 232 to be recessed rearward.

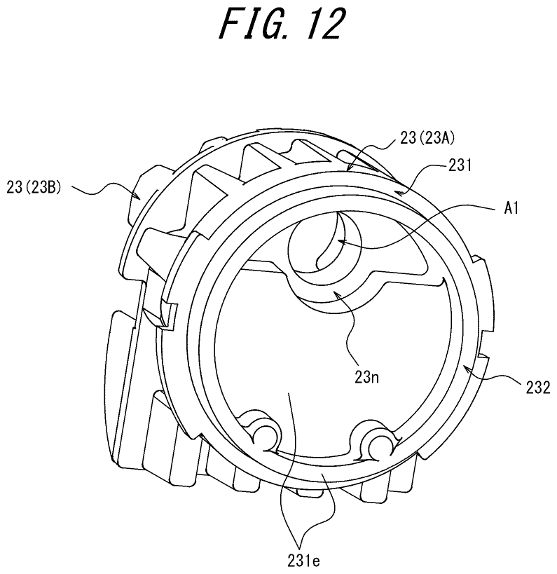

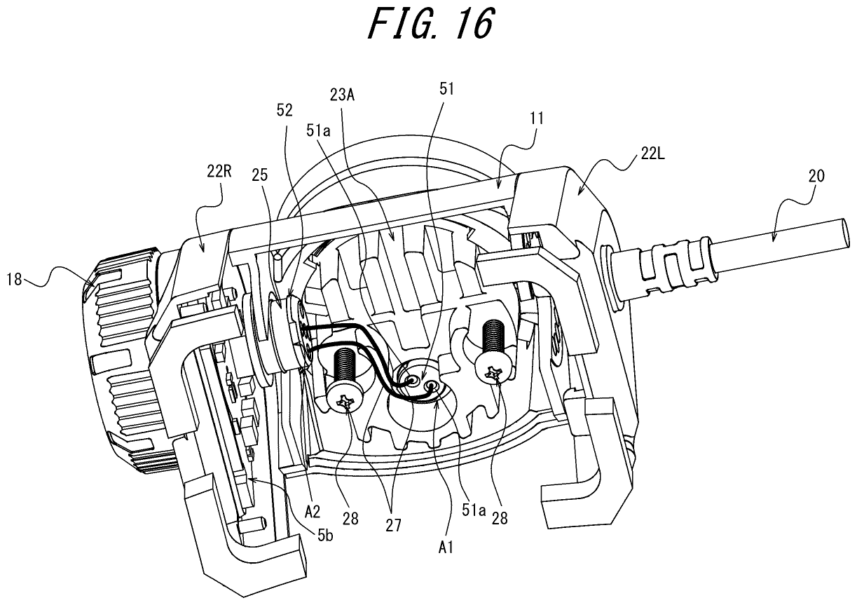

FIG. 12 illustrates the first heat-radiating means 23A and the second heat-radiating means 23B that are assembled together. As illustrated in FIG. 12, in the present embodiment, the body 231 of the first heat-radiating means 23A has a through-hole A1, which opens in the recessed portion 23n. As illustrated in FIG. 13, in the present embodiment, the body 231 of the first heat-radiating means 23A is provided with a cable gasket 51. The cable gasket 51 is press-fitted into the through-hole A1 provided in the body 231, thereby sealing the through-hole A1. The cable gasket 51 has wiring holes 51a, through which wires 27 (see FIG. 16) are made to hermetically pass to be connected to the light-emitting device 3 and the circuit elements 5a. The cable gasket 51 is made of an elastic material such as silicon.

Referring to FIG. 14, for example, in the present embodiment, the head body 1A is rotatably supported by the head frame 1B.

FIG. 14 is a sectional view of the headlight 10A and schematically illustrates a section containing the rotation axis, O1, thereof.

As illustrated in FIG. 14, in the present embodiment, the two side frames 16 of the head frame 1B are provided with respective rotation shafts 25, which are rotatably supported by the head body 1A. In the present embodiment, the side base 21 of each of the side frames 16 has the rotation shaft 25, which projects inward. In the present embodiment, the rotation shaft 25 is rotatably supported at a through-hole 1h, which is defined by the front body 11 and the rear body 12. In the present embodiment, the rotation shaft 25 and the through-hole 1h are located on the same rotation axis, which is O1. Therefore, the head body 1A and the head frame 1B are rotatable in the peripheral direction on the rotation axis O1.

As illustrated in FIG. 14, in the present embodiment, the light-emitting device 3 is located on the inner side of the front cylindrical part 232 of the first heat-radiating means 23A and is attached to the first heat-radiating means 23A with the aid of the mounting board 24. In the present embodiment, an apical part of the light-emitting device 3 is exposed through the opening A26 (see FIG. 9) provided in the lens spacer 26.

As illustrated in FIG. 14, in the present embodiment, the light-emitting device 3 housed in the light-emitting-device-housing space S1 is located in a hermetic space S1s, which is defined by the lens 2, the front ring 13, and the first heat-radiating means 23A. In the present embodiment, the light-emitting-device-housing space S1 is provided on the inner side of the front body 11 and the rear body 12.

In the present embodiment, the front end of the light-emitting-device-housing space S1 is closed by the lens 2.

In the present embodiment, the lens 2 is attached to the first heat-radiating means 23A, and the gap between the lens 2 and the first heat-radiating means 23A is sealed by the heat-sink gasket 29 interposed between the front cylindrical part 232 of the first heat-radiating means 23A and the front ring 13. In the present embodiment, the rear end of the light-emitting-device-housing space S1 is closed by the rear body 12.

In the present embodiment, the heat-sink gasket 29 is fitted on the outer peripheral surface of the front cylindrical part 232 of the first heat-radiating means 23A. Hence, in the present embodiment, a space in the light-emitting-device-housing space S1 that is defined by the lens 2, the front ring 13, and the first heat-radiating means 23A serves as the hermetic space Sls. Thus, in the present embodiment, the space that houses the light-emitting device 3 is made waterproof.

In the present embodiment, the first heat-radiating means 23A of the heat-radiating means 23 includes the front cylindrical part 232 that houses the light-emitting device 3, and the recessed portion 23n is provided on the inner side of the front cylindrical part 232. As illustrated in FIG. 13, for example, in the present embodiment, the recessed portion 23n is provided on the inner side of the front cylindrical part 232 of the first heat-radiating means 23A by causing a portion of the front end 231e of the body 231 to be recessed rearward. The recessed portion 23n is capable of storing air. The air stored in the recessed portion 23n serves as heat-insulating air.

Referring to FIG. 14, in the present embodiment, the switch knob 18 is rotatable in the peripheral direction on an axis O2, whereby the intensity (quantity) of the light to be emitted from the light-emitting device 3 is changeable in a graded manner. In the present embodiment, the switch knob 18 is urged outward relative to the side cover 22 by an elastic member 18b, which is a spring or the like. In the present embodiment, the switch 17 is made of an elastic member. The switch 17 includes a pushing piece 17a. The switch element 5a1 on the board 5b operates synchronously with the pushing of the switch 17 and is turned on or off when the pushing piece 17a of the switch 17 is pushed. In the present embodiment, the switch element 5al is turned on when pushed by the pushing piece 17a of the switch 17. In the present embodiment, when the switch element 5a1 is turned on, the intensity (quantity) of the light emitted from the light-emitting device 3 is maximized for a predetermined time period.

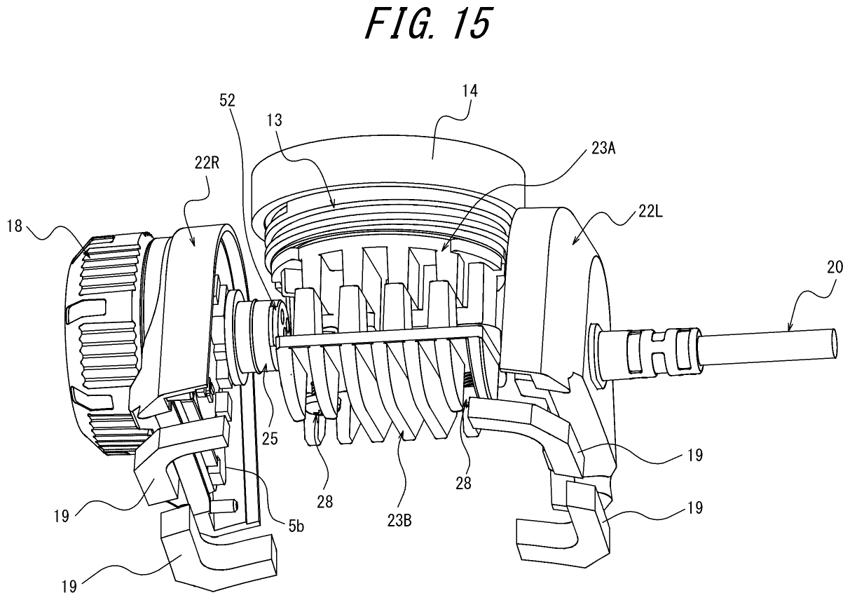

FIG. 15 is a perspective view of the headlight 10A, with the head body 1A and a part of the head frame 1B removed. As illustrated in FIG. 15, in the present embodiment, the first heat-radiating means 23A and the second heat-radiating means 23B are coupled to each other with screws 28 into a unit.

FIG. 16 is a perspective view of the headlight 10A, with the head body 1A, the part of the head frame 1B, and a part (the second heat-radiating means 23B) of the heat-radiating means 23 removed.

As illustrated in FIG. 16, in the present embodiment, the first heat-radiating means 23A has the through-hole A1. The wires 27 connecting the light-emitting device 3 and the circuit elements 5a of the control board 5 to each other are routed through the through-hole A1. In the present embodiment, the through-hole A1 is press-fitted therein with the cable gasket 51. The cable gasket 51 seals the hermetic space S1s that is provided in the light-emitting-device-housing space S1 and in which the light-emitting device 3 is placed. The cable gasket 51 is made of an elastic material such as silicon. In the present embodiment, the wires 27 pass through the respective wiring holes 51a provided in the cable gasket 51, with the sealability of the cable gasket 51 maintained.

As illustrated in FIG. 16, in the present embodiment, the rotation shaft 25 has on the inner side thereof a through-hole A2. The wires 27 that connect the light-emitting device 3 and the circuit elements 5a of the control board 5 to each other are routed through the through-hole A2. In the present embodiment, the through-hole A2 is press-fitted therein with a plug (control-board sealing member) 52. The plug (hermetic stopper) 52 seals the control-board-housing space S2. The plug 52 is made of an elastic material such as silicon. In the present embodiment, the wires 27 pass through the plug 52, with the Sealability of the plug 52 maintained.

As illustrated in FIG. 16, the wires 27 between the light-emitting device 3 and the control board 5 are each covered with a silicon tube, thereby being made waterproof.

As illustrated in FIG. 14, the headlight 10A includes the light-emitting device 3, the control board 5, the light-emitting-device-housing space S1 that houses the light-emitting device 3, and the control-board-housing space S2 that houses the control board 5. The light-emitting-device-housing space S1 and the control-board-housing space S2 are different spaces.

In the present embodiment, the control-board-housing space S2 is provided inside the head frame 1B. On the other hand, in the present embodiment, the light-emitting-device-housing space S1 that houses the light-emitting device 3 is provided inside the head body 1A.

In the headlight 10A, since the light-emitting-device-housing space S1 and the control-board-housing space S2 are separate from each other, heat generated from the light-emitting device 3 is less likely to be transmitted to the control board 5. Specifically, such a configuration minimizes the deterioration or trouble of the control board 5 that may be caused by the heat generated from the light-emitting device 3.

In contrast, for example, in each of the known headlights disclosed in PTL 1 and 2, the light-emitting device, the control board, and the heat-radiating means such as a heat sink are arranged in series, and heat is radiated around the control board.

If, however, the known headlight including such heat-radiating means is used with a constantly high power output and for long hours, the control board is inevitably affected. Therefore, the power output (light quantity) of such a light-emitting device is controlled to decrease gradually.

In such a solution, however, since the light quantity of the headlight decreases with the passing of usage time, the user may experience discomfort, which means that there is room for improvement.

Hence, another solution has been conceived in which the power output of the light-emitting device is suppressed to a certain ratio with respect to the maximum light quantity of the light-emitting device. Nevertheless, it is difficult to continuously emit light with a high power output. It is even difficult to gradually decrease the light quantity.

In view of the above, the headlight 10A includes the light-emitting-device-housing space S1 and the control-board-housing space S2 that are separate from each other, so that the control board 5 is less likely to be affected by the heat generated from the light-emitting device 3. Such a configuration enables the long-hour use of the headlight 10A with no decrease in the power output of the light-emitting device 3, even if the power output of the light-emitting device 3 is kept maximum.

Furthermore, in the headlight 10A, since the control board 5 is located separately from the light-emitting device 3, the heat-radiating means 23 is allowed to be located adjacent to the light-emitting device 3. Thus, the heat generated from the light-emitting device 3 is directly released through, for example, the heat-radiating means 23.

Thus, the headlight 10A is provided as a headlight that is excellent in terms of protection from the heat generated by the light-emitting device 3.

Furthermore, in the headlight 10A, as described above, since the control board 5 is located separately from the light-emitting device 3, the heat generated from the light-emitting device 3 is efficiently released. Therefore, the headlight 10A is attachable to any headwear such as a hat, other than a helmet. Moreover, the headlight 10A is directly wearable on the head of the user.

In the headlight 10A, as a result of separating the control board 5 from the light-emitting device 3, the light-emitting-device-housing space S1 and the control-board-housing space S2 are individually sealable with the use of sealing members such as the heat-sink gasket 29, the cable gasket 51, the plug 52, and the like, as in the present embodiment. Thus, the headlight 10A has a waterproof function. Consequently, for example, there is no need to suspend the work even if it rains.

Furthermore, in the headlight 10A, since the power output of the headlight 10A is maintained to be constant with no decrease, any reduction in the power output of the headlight 10A directly relates to the exhaustion of the power source. Therefore, in the headlight 10A, the time of exhaustion (usage time) of the power source is known clearly.

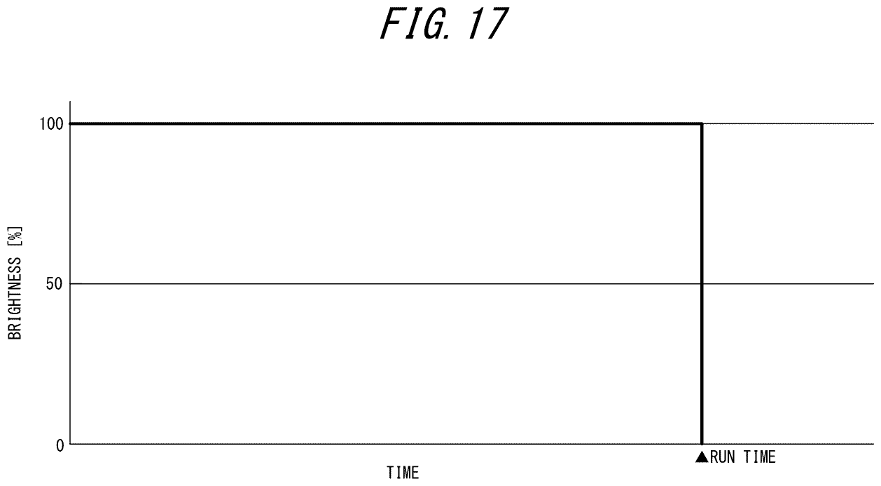

FIG. 17 illustrates chronological analysis data on the brightness of the light emitted from the headlight 10A when the headlight 10A continues to be used with a constant power output of 100%. In the analysis data illustrated in Fig. 17, the vertical axis represents lumen (Im), and the horizontal axis represents lighting time (h). As illustrated in FIG. 16, in the headlight 10A, the power output of the headlight 10A is maintained to be constant with no decrease. Therefore, with the headlight 10A, the time of exhaustion of the power source (the possible duration of lighting) is known clearly.

Furthermore, for example, referring to FIG. 14, the headlight 10A includes the head body 1A and the head frame 1B. The light-emitting-device-housing space S1 is provided in the head body 1A. The control-board-housing space S2 is provided in the head frame 1B. Therefore, as illustrated in FIG. 17, the headlight 10A is usable for long hours even if the power output of the light-emitting device 3 is kept maximum, with the size of the headlight 10A being the same as or smaller than the size of the known ones.

As described above, the headlight 10A is allowed to have the same size as the known ones. In the headlight 10A, the control board 5 is placed at a position separate from the head body 1A. Therefore, if the headlight 10A is maintained to have the same size as the known ones, the size of the heat-radiating means 23 is allowed to be increased by an amount corresponding to a free space obtained by placing the control board 5 at a separate position. In such a configuration, the power of the light to be outputted from the headlight 10A is allowed to be increased by the amount of increase in the efficiency of heat radiation.

Alternatively, in the headlight 10A, since the control board 5 is placed at a position separate from the head body 1A, the size of the head body 1A is allowed to be reduced by an amount corresponding to a free space obtained in replacement of the control board 5. As another alternative, if the control board 5 is placed at a position separate from the head body 1A and from the head frame 1B as to be described below, the size of at least one of the head body 1A and the head frame 1B is allowed to be reduced by an amount corresponding to a free space obtained in replacement of the control board 5.

In the headlight 10A, the head frame 1B includes the base frame 15 and the two side frames 16, and the control-board-housing space S2 may be provided in one of the two side frames 16. Such a configuration facilitates the Separation of the control board 5 from the light-emitting device 3.

In the headlight 10A, one of the two side frames 16 (the right side frame 16R) is provided with the switch 17, and the right side frame 16R has the control-board-housing space S2. Such a configuration enables the switching operation on the control board 5 with a simple structure.

In the present embodiment, the switch 17 and the control-board-housing space S2 are provided to the right side frame 16R. Alternatively, the switch 17 and the control-board-housing space S2 may be provided to the left side frame 16L.

In the headlight 10A, one of the two side frames 16 (left side frame 16L) is provided with the power cable 20 connected to the power box 40, and the left side frame 16L or the power box may have the control-board-housing space S2. Such a configuration also enables the switching operation on the control board 5 with a simple structure.

FIG. 18 is a schematic perspective view of a headlight 10B according to a second embodiment of the present invention. As illustrated in FIG. 18, in the present embodiment, the control board 5 is provided as a discrete control unit 50 and is separate from the head frame 1B. In the present embodiment, the power cable 20 is connected to the power box 40. In the present embodiment, the control unit 50 (control board 5) is interposed in the power cable 20. Thus, the control board 5 may be provided as a discrete unit that is separate from the head body 1A and from the head frame 1B.

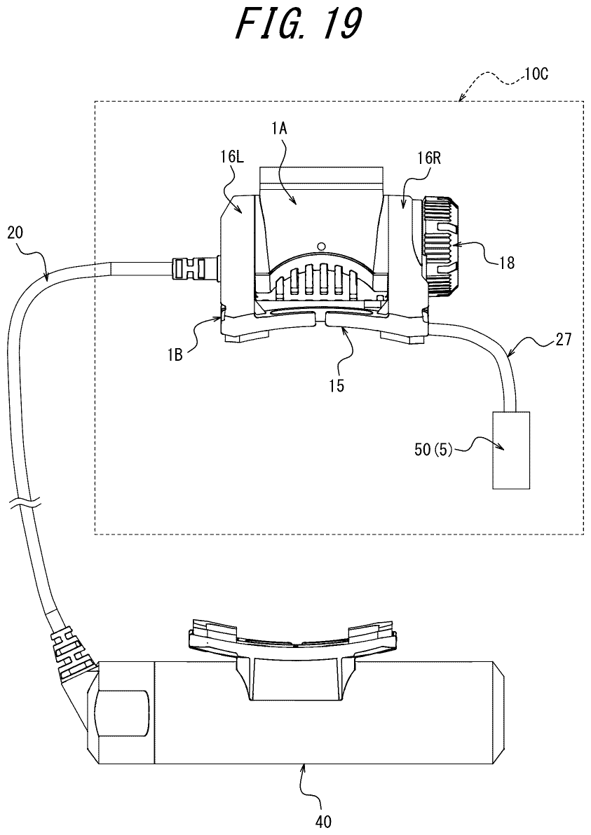

FIG. 19 is a schematic perspective view of a headlight 10C according to a third embodiment of the present invention. As illustrated in FIG. 19, in the present embodiment as well, the control board 5 is provided as a discrete control unit 50 and is separate from the head frame 1B. In the present embodiment, the wires 27 are extended from the left side frame 16L, and the control unit 50 is connected to the wires 27. In such a configuration, the control board 5 in the control unit 50 may be constituted by, for example, only a power board (power unit) configured to control the electric current to be supplied from the power box 40 to the light-emitting device 3.

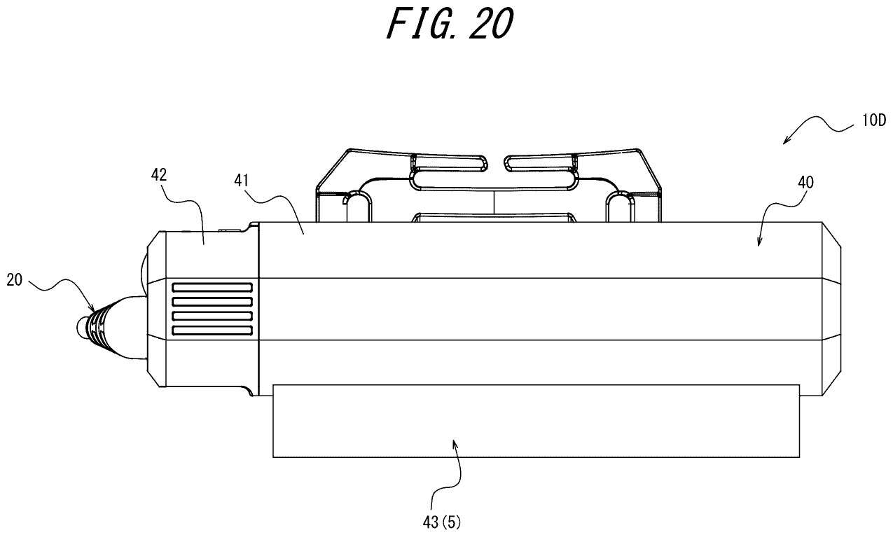

FIG. 20 is a diagram schematically illustrating a power box 40 for a headlight 10D according to a fourth embodiment of the present invention. In the present embodiment, the control board 5 is placed in the power box 40. In the present embodiment, the size of the case of the power box 40 is increased, whereby a free space is provided for housing the control board 5. As illustrated in FIG. 20, in the present embodiment, the power box 40 includes a power case 41 and a lid 42. The lid 42 is detachable from the power case 41. In the present embodiment, the power cable 20 is connected to the lid 42. In the present embodiment, the size of the power case 41 is increased, whereby a case 43 is provided to the power case 41 for the control board 5 to be housed. Thus, in the present embodiment, the power box 40 is allowed to house the control board 5 in the free space obtained by increasing the size of the power case 41.

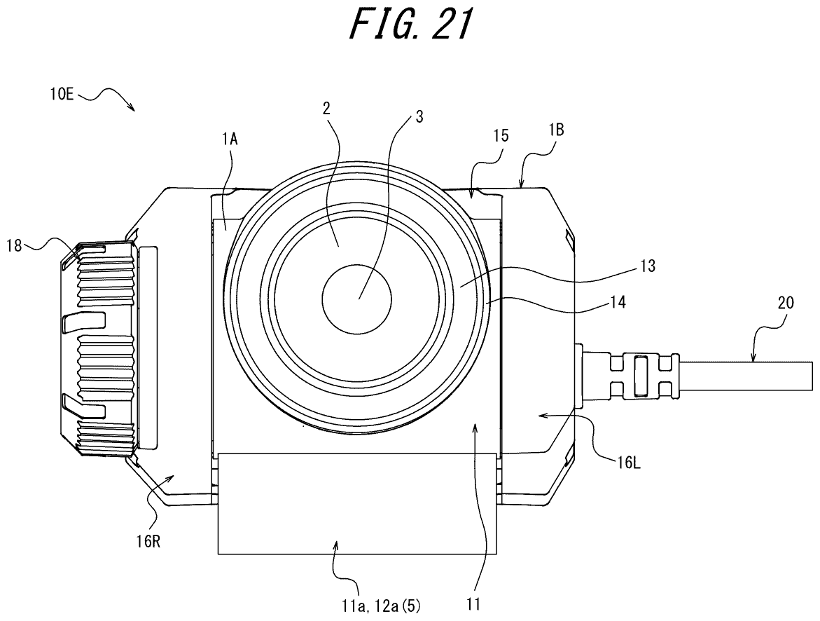

FIG. 21 is a schematic front view of a headlight 10E according to a fifth embodiment of the present invention.

In the present embodiment, the control board 5 is placed in the head body 1A. In the present embodiment, the size of at least one of the front body 11 and the rear body 12 of the head body 1A is increased, whereby a free space is provided for housing the control board 5. As illustrated in FIG. 21, in the present embodiment, the sizes of the front body 11 and the rear body 12 are increased, whereby an increased area 11a and an increased area 12a are provided in the front body 11 and the rear body 12, respectively, to provide an internal space for housing the control board 5. Thus, in the present embodiment, the head body 1A is allowed to house the control board 5 in the free space obtained by increasing the size of the head body 1A.

In the present embodiment, the power cable 20 and the power box 40 are provided to the left side frame 16L. Alternatively, the power cable 20 and the power box 40 may be provided to the right side frame 16R.

In the headlight 10A, the head body 1A is rotatably supported by the head frame 1B. In such a configuration, the direction of light emission is adjustable in the top-bottom direction, which provides a headlight with increased convenience of use.

The headlight 10A further includes the heat-radiating means 23. The heat-radiating means 23 is housed in the light-emitting-device-housing space S1 and is located adjacent to the light-emitting device 3. Such a configuration enhances the protection from the heat generated by the light-emitting device 3. In the headlight 10A particularly, the control board 5, which has been placed adjacent to the light-emitting device 3, is placed separately from the light-emitting device 3. Therefore, the number of the heat-radiating means 23 to be provided may be increased by an amount accommodatable by the space that has been intended for the control board 5. While the present embodiment employs two heat-radiating means 23, three or more heat-radiating means 23 may be employed.

In the headlight 10A, the heat-radiating means 23 is a heat sink. In such a case, the heat generated from the light-emitting device 3 is efficiently released with a simple structure, such as an increased number of heat-radiating plates. The heat sink to be employed may be made of a highly heat-conductive material, such as silver or copper. However, if the heat sink is made of an aluminum alloy, the weight and the manufacturing cost are reduced.

As described above, the headlights 10A to 10E according to the above embodiments are each provided as a headlight that is excellent in terms of protection from heat generated by a light-emitting device.

FIG. 22 is a diagram schematically illustrating a shell-type LED device serving as the light-emitting device 3 of any of the headlights 10A to 10E. As illustrated in FIG. 22, the shell-type LED device is obtained by placing an LED chip 30 on a leadframe 31, providing sealing resin (fluorescent material) 32 thereover, and placing a lens 33 thereover. The lens 33 is made of, for example, epoxy resin.

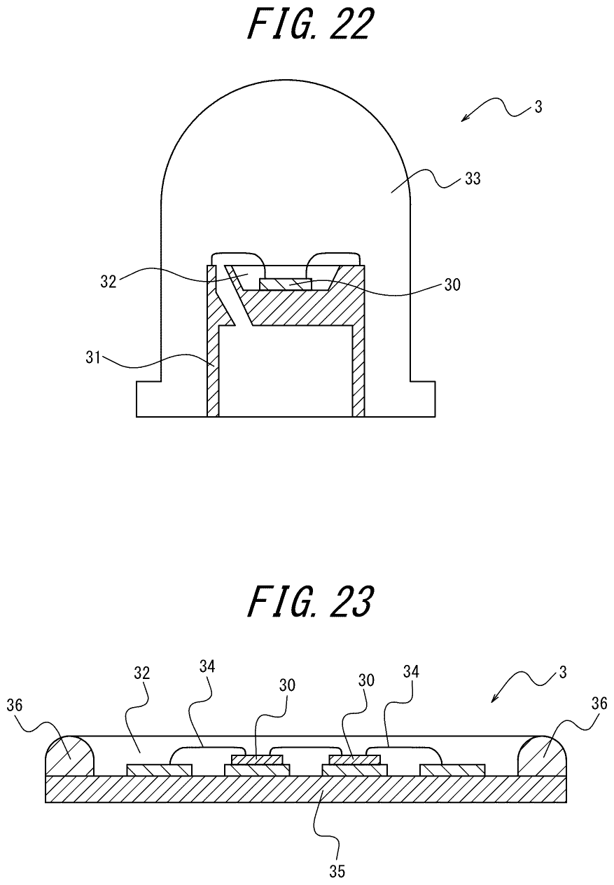

FIG. 23 is a diagram schematically illustrating a chip-on-board LED device that is available as the light-emitting device 3 of any of the headlights 10A to 10E. As illustrated in FIG. 23, the chip-on-board LED device is obtained by placing LED chips 30 and metal wires 34 on a board 35 and providing sealing resin (fluorescent material) 32 over the board 35. Reference sign 36 denotes a bank provided on the board 35.

The above description only provides exemplary embodiments of the present invention, and various changes can be made thereto in accordance with the appended claims. For example, the light-emitting device 3 may be a light bulb (such as a filament light bulb) instead of an LED. In each of the headlights 10A to 10E, if the power output (light quantity) of the light-emitting device 3 is suppressed to a low level, the heat-radiating means 23 may be omitted.

### REFERENCE SIGNS LIST

10A headlight (first embodiment)
10B headlight (second embodiment)
10C headlight (third embodiment)
10D headlight (fourth embodiment)
10E headlight (fifth embodiment)
1A head body
1B head frame
1h through-hole
2 lens
3 light-emitting device
5 control board
5a circuit element
5a1 switch element
5b board
11 front body
11a increased area of front body
12 rear body
12a increased area of rear body
12f slope formed at rear body
13 front ring
14 front-ring cover
15 base frame
15s slit opening
16 side frame
16R right side frame
16L left side frame 17 switch
18 switch knob
19 cushion member
20 power cable
21 side base of side frame
22 side cover of side frame
21R right side base of right side frame
22R right side cover of right side frame
21L left side base of left side frame
22L left side cover of left side frame
23 heat-radiating means
23A first heat-radiating means
231 body of first heat-radiating means
232 front cylindrical part of first heat-radiating means
23B second heat-radiating means
23n recessed portion
24 mounting board
25 rotation shaft
26 lens spacer
27 wire
28 screw
29 heat-sink gasket (heat-radiating-means sealing member: hermetic stopper)
40 power box
41 power case
42 lid
50 control unit
51 cable gasket (hermetic stopper)
52 plug
C collar
h1 vent hole provided in rear body
O1 rotation axis

1. A headlight comprising:
a light-emitting device;
a control board;
a light-emitting-device-housing space that houses the light-emitting device; and
a control-board-housing space that houses the control board,
wherein the light-emitting-device-housing space and the control-board-housing space are different spaces.

2. The headlight according to claim 1, further comprising:
a head body and a head frame,
wherein the light-emitting-device-housing space is provided in the head body, and the control-board-housing space is provided in the head frame.

3. The headlight according to claim 1, further comprising:
heat-radiating means,
wherein the heat-radiating means is housed in the light-emitting-device-housing space and is located adjacent to the light-emitting device.

4. The headlight according to claim 2, further comprising:
heat-radiating means,
wherein the heat-radiating means is housed in the light-emitting-device-housing space and is located adjacent to the light-emitting device.
